(19) United States
(12) Patent Application Publication
(10) Pub. No.: US 2011/0249420 A1
(43) Pub. Date: Oct. 13, 2011

(54) Window mounted electrical outlet system

(76) Inventors: John Prim, Willoughby, OH (US); Steven D. Bolyard, Euclid, OH (US); John L. Prim, Cleveland, OH (US)

(21) Appl. No.: 12/932,917

(22) Filed: Mar. 9, 2011

Related U.S. Application Data
(60) Provisional application No. 61/342,300, filed on Apr. 12, 2010.

(51) Int. Cl. H05K 7/02

(52) U.S. Cl. 361/807

(57) ABSTRACT

A window mounted modular system of stackable planks attached with electric components to provide electrical power from outdoor sources for use by indoor appliances.

### TECHNICAL FIELD

The present invention relates generally to electrical power outlets, and more particularly to a modular system that supplies a room of a building with electrical power from sources other than the utility grid.

The invention is an inexpensive and modular means to quickly install electrical outlets from alternative energy sources in buildings such as, but not limited to, cabins.

In the case of power outages from various inclement weather conditions, the invention eliminates extension cords running through open doors or windows from alternative electrical sources to power lighting or appliances. In addition, it provide's an affordable means to connect local renewable energy production to the utility grid.

Renewable energy sources are increasingly popular in order to provide emergency power when the utility grid fails. Other reasons include finding an alternative to increasing energy cost and eliminating carbon emissions in order to reduce the impact of global warming.

However, widespread adoption of such energy sources have been limited due to difficult and expensive connection to a building. Even in photovoltaic energy systems, which are inherently modular, this inability to quickly, affordably, and effectively connect the power source to electric outlets exists.

As will be shown, the present invention provides a solution to these connection problems.

### PRIOR ART

Since the earliest days of electrical generation, various means have been devised to distribute such power throughout a building. For example, Markel (U.S. Pat. No. 460,725) developed a modular conduit strip for branching power to provide room lighting in a building.

As electric appliances became common, new components developed to enhance the safety of the existing electrical infrastructure. Blonder's outlet locking cover (U.S. Pat. No. 3,293,588) is an example of this progress. It's an adaptable module for locking down various cord plugs to different outlet types.

One sees this theme of modularity again with Propst et al (U.S. Pat. No. 4,255,611). They had devised an indoor electrical distribution system based on portable wall panels for offices. As they point out, significant savings was achieved because the electric lines were mounted to the outside of the portable walls, rather than being pulled through existing walls.

Muthelar also demonstrates a modular means to distribute power in an office building (U.S. Pat. No. 4,982,536). His conduit device is a hollow molding mounted to window or wall parapets. It contains accessible wire raceways to distribute power and provides support for electric outlets.

Paninno's window outlet is a clever solution to provide utility power to outdoor electric equipment, such as a hedge clipper. His hollow enclosure is adaptable to different window lengths for providing an outdoor outlet where it's most needed.

All the above share the common recognition of working within the existing building structure. But all are based on extending distribution of utility grid power. None allow for easy local distribution of alternative energy sources. And while each provide for electric outlets in some modular form, none provide for easy expansion of other electrical components.

### INVENTION SUMMARY

The present invention uses design for manufacturing principles to resolve problems for connecting alternative energy sources to a building. Using this approach, the objectives of the present invention include the following:

Reduced Construction Cost. The invention can be manufactured from common and recyclable materials. The main components are simple and inexpensive to manufacture utilizing existing technology. The system eliminates specialized fixtures for mounting other components. Modular flexibility allows the invention to be very adaptable.

Reduced Operating Cost. Improved system integration reduces installation cost. Individual electrical components are easily serviceable, reducing maintenance cost. Mass-produced electrical components fit in modular fashion to the system, in turn, making it easier to repair or replace such components.

Reliability and Security. The system is highly reliable as there are almost no moving parts. The system is a means to provide emergency power when the utility grid fails. It can also provide renewable energy to the utility grid, reducing utility bills.

Distribution Independence. The system overcomes the existing electrical distribution in a building. Buildings can contain old knob and tube wiring, aluminum wiring, romex, wire raceways, or wire conduits. The system is independent of existing building wiring. This allows widespread adoption of alternate energy sources.

Environmental Impact. The system is easily disassembled. Regardless of whether the system is constructed of wood, plastic, metal, or a combination of such materials; all of it is easily disassembled for reduce, reuse, and recycle strategies. This cradle to cradle approach greatly reduces environmental impact.

The components of this invention are known in the art and based on technology that is approximately 100 years old. It's the new and non-obvious combination of these components that makes the present invention feasible. Other advantages of the invention will become apparent in the various embodiments.

### DRAWING DESCRIPTION

FIG. 1 depicts a perspective view of a basic dividing plank mounted with an electrical box and outlet.

FIG. 2 is an exploded view of the inside face of standard dividing planks, provided with an outlet and cleat supports.

FIG. 3 is an exploded view of the outside face of standard dividing planks, provided with an electrical box and cleat supports.

FIG. 4 is a semi-exploded, perspective view of stacked dividing planks, provided with electric components, cleat supports, and an electrical box.

FIG. 5 is a perspective view of the invention as it would appear mounted in a sliding window.

### EMBODIMENT DESCRIPTIONS

The central component in all embodiments of the invention is the dividing plank. The dividing plank is made of wood, plastic, metal, or a combination of such materials.

While the embodiments and drawings demonstrate the invention for installation in a vertical sliding window, it's not limited to this type of installation. The invention is easily adapted for horizontal installations, such as in sliding glass doors.

### Basic Embodiment

The basic embodiment uses, but is not limited to, an Alternating Current (AC) electrical outlet. The outlet is, but not limited to, a Ground Fault Circuit Interrupter (GFCI) type receptacle. In the event of a ground fault, a GFCI will trip and quickly stop the flow of electricity to prevent serious injury.

Referring to FIG. 1; the GFCI receptacle 1 is attached to the surface mount box 2. This box provides a fixed mounting for the GFCI receptacle on the dividing plank 3. It also provides a barrier to wiring connections from the GFCI receptacle to the outside electric cord plug.

The outlet assembly is mounted to the inside face of the dividing plank. Directly opposite of the surface mount box, on the outside face of the dividing plank, is mounted a cable connector (not shown). The cable connector securely holds an electric cord plug. This plug facilitates connection to an alternative electrical source.

The dividing plank is wide enough to secure the surface mount box while being securely clamped by a closed sliding window. The plank is long enough to reach from one inner side edge of the window sill to the other, creating a complete seal from the outside environment.

### Standard Embodiment

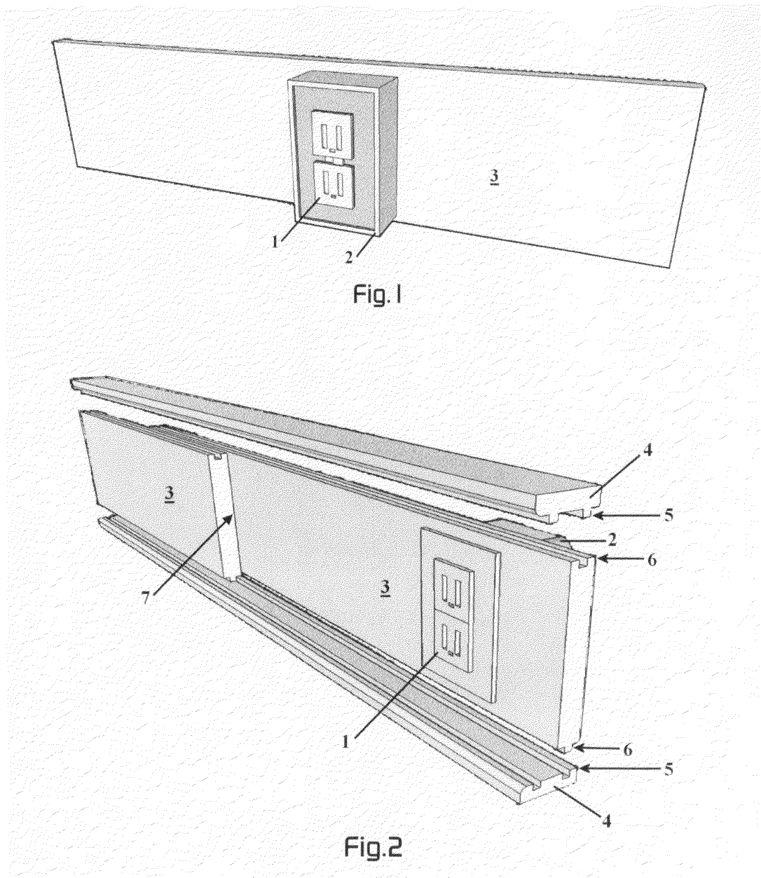

Referring to FIG. 2, the AC outlet 1 is flush mounted to the inside face of a dividing plank 3. An electrical box 2 is mounted to the outside face of the plank 3. Each dividing plank 3 has tongue and groove joints 6 at the top and bottom for insertion into the mounting cleats 4. The mounting cleats also have tongue and groove joints 5.

The dividing planks are of a standard dimension, one closely spaced 7 in front of another. This enables faster installation in a window, as one standard dividing plank can slide to fill the window length, sealing the building interior from the outside environment.

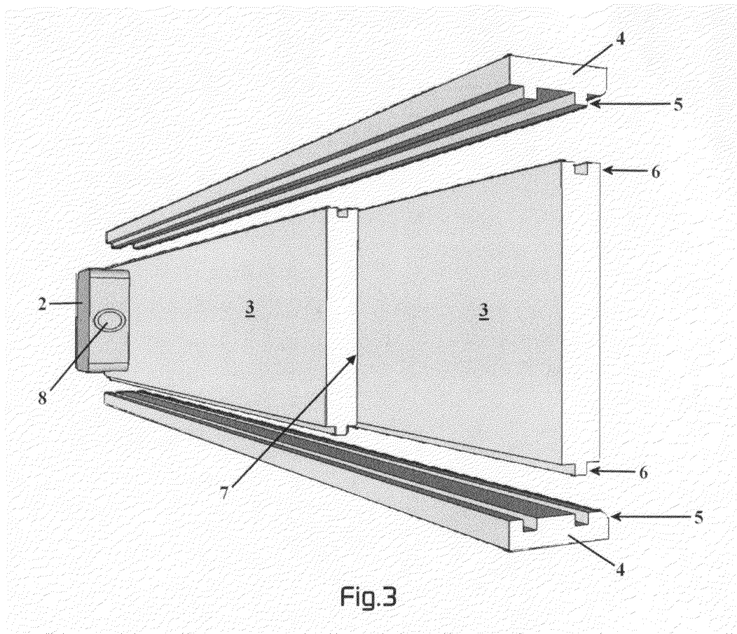

FIG. 3 shows an outside view of the same parts described in FIG. 2. The cable connector knock out 8 is now visible on electrical box 2.

### Preferred Embodiment

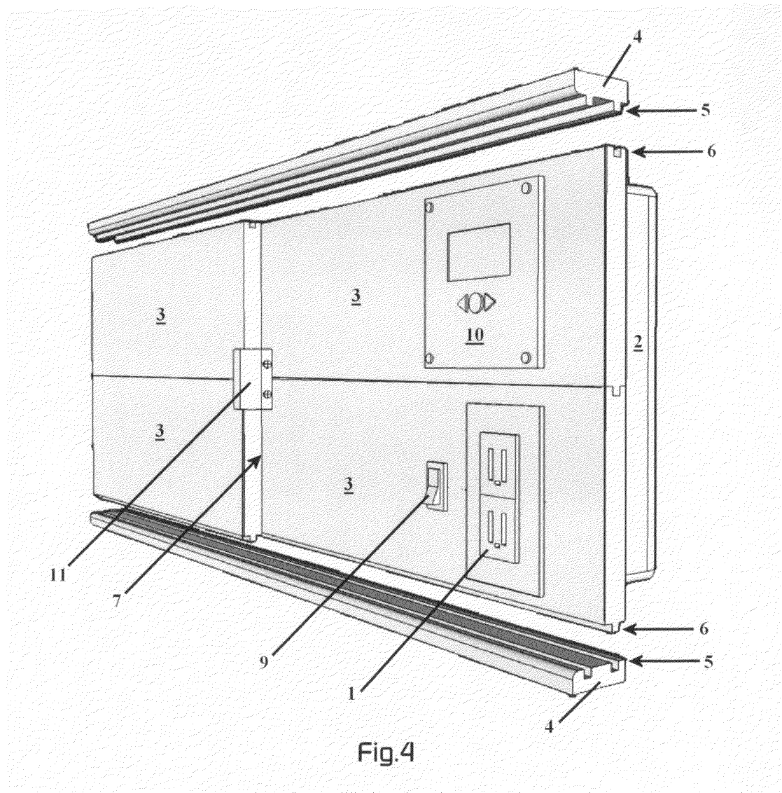

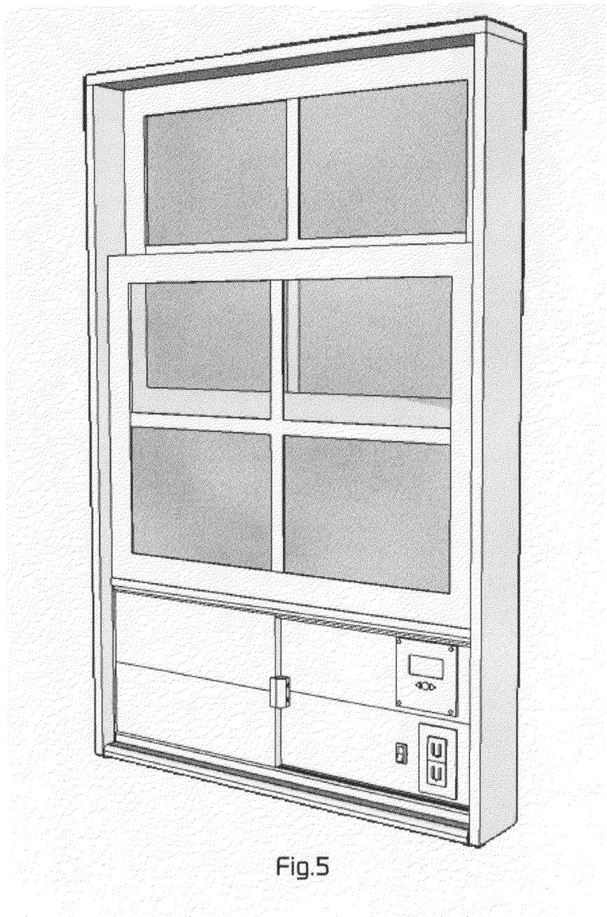

Referring to FIG. 4, an AC outlet 1 and switch 9 are flush mounted to the inside face of the bottom dividing plank 3. The switch turns power to the outlet on and off. It prevents a battery bank from being drained from phantom loads by indoor appliances.

A power meter 10 is flush mounted to the inside face of the top dividing plank 3. The power meter provides information on how much energy is being produced by a photovoltaic array and how much energy is available from a battery bank. It can also be used to determine how much energy has been consumed by appliances.

Each dividing plank 3 and mounting cleat 4 have tongue and groove joints (5 and 6). Additional dividing planks can be installed one on top another to almost the maximum height of a window opening as additional electric components are needed (not shown).

Two dividing planks 3 are secured together with a handle cleat 11. The planks are closely spaced 7 in front of one another. This allows sliding to fill the window length, sealing the building interior from the outside environment.

An electrical box 2 is mounted to the outside face of the two dividing planks 3 stacked one on top the other. All the wire connections for the electrical components are made in this panel.

Knock outs (not shown) on the electric box 2 provide a means to connect outdoor alternative energy sources for indoor use.

FIG. 5 is how the preferred embodiment appears from inside a building when installed in a window.

### Other Embodiments

A grid-tie converter (not shown) is mounted to the outside face of stacked planks. Grid-tie converters transform D.C. power from renewable energy sources into conditioned A.C. power. This conditioned power is then provided to the utility grid through an indoor building outlet.

An electric box is mounted to the inside face of stacked planks in order to pass through an A.C. cord from the converter to an indoor building outlet. This provides local renewable energy to the utility grid.

The embodiments demonstrate the inventions novel feature of modular component flexibility while still maintaining effective system integrity. It's understood that this invention is not limited to the disclosed embodiments. Therefore, the claims should be accorded a broad interpretation to encompass all such modifications.

1. A window mounted, modular electric outlet system to provide indoor power from outdoor alterative energy sources, comprising of: (a) a dividing plank, (b) electric components, (c) electrical boxes.

2. (canceled)

3. The system in claim 1, wherein a dividing plank has tongue and groove joints along parallel edges.

4. The system in claim 1, wherein a plank is connected along a parallel edge to another plank or mounting cleat.

5. (canceled)

6. The system in claim 1, wherein electric components are mounted to either face of the dividing plank.

7. The system in claim 1, wherein electrical boxes are mounted to either face of the dividing plank.
